(19) United States
(12) Patent Application Publication
(10) Pub. No.: US 2015/0278010 A1
(43) Pub. Date: Oct. 1, 2015

(54) DIGITAL DEVICE

(71) Applicant: FREESCALE SEMICONDUCTOR, INC., Austin, TX (US)

(72) Inventors: Michael Rohleder, Unterschleissheim (DE); Carmen Klug-Mocanu, Aying (DE); Joachim Kruecken, Munich (DE)

(73) Assignee: FREESCALE SEMICONDUCTOR, INC., Austin, TX (US)

(21) Appl. No.: 14/646,392

(22) PCT Filed: Nov. 23, 2012
(86) PCT No.: PCT/IB2012/056675

§ 371 Date: May 21, 2015

(51) Int. Cl. G06F 11/10; H03M 13/09

(52) U.S. Cl. CPC G06F 11/1004; H03M 13/096

(57) ABSTRACT

A digital device includes one or more requestor units, one or more responder units, and a bus. Each responder unit is connected to the requestor units via the bus and includes a plurality of responder elements which are accessible by the requestor units via the bus and which include one or more critical responder elements. The digital device further includes one or more wrapper units. Each wrapper unit includes an interface unit arranged to enable the requestor units to access the responder elements of the respective responder unit associated with the respective wrapper unit and a checksum unit arranged to respond to any write access to any one of the critical responder elements by computing and storing a reference checksum. The checksum unit is arranged to compute the reference checksum by applying a checksum algorithm to a subset of the critical responder elements, including at least the write-accessed critical responder element.

### FIELD OF THE INVENTION

This invention relates to a digital device.

### BACKGROUND OF THE INVENTION

A variety of electronic and optoelectronic memory devices are known in the art. A digital device may comprise a plurality of memory elements. A memory element is a structure for storing one or more information bits. A flip-flop or a group of flip-flops is an example of a memory element. Memory elements that are used in today's devices can be very reliable when the device is sufficiently well protected against perturbations from its environment. Such perturbations may include, for example, photon or neutron impact or collisions with alpha particles. For example, a neutron colliding with a flip flop may reverse the state of the flip-flop.

Various techniques for helping to ensure the integrity of data stored in a digital device are known in the art. One example includes the use of triple voting flip-flops (TVF). In another approach, a checksum is generated for the data of interest. By recomputing the checksum for the data of interest at a later point in time and comparing it with the original checksum, it may be determined whether the data has changed or not. For example, US patent application publication no. US 2012/0036400 A1 (Miller) describes a data processing system that includes a plurality of peripherals in which the integrity of configuration information may be checked by means of an error syndrome generated by a peripheral bus interface when a requestor unit of the data processing system has initiated a write operation.

### SUMMARY OF THE INVENTION

The present invention provides a digital device as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 schematically shows an example of an embodiment of a digital device.

FIG. 2 schematically shows an example of an embodiment of a responder unit.

FIG. 3 schematically shows an example of an embodiment of a wrapper unit.

FIG. 4 schematically shows an example of an embodiment of a shared unit.

FIG. 5 shows a flow chart of an example of an embodiment of a method of operating a digital device.

### DETAILED DESCRIPTION OF THE PREFERRED EMBODIMENTS

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

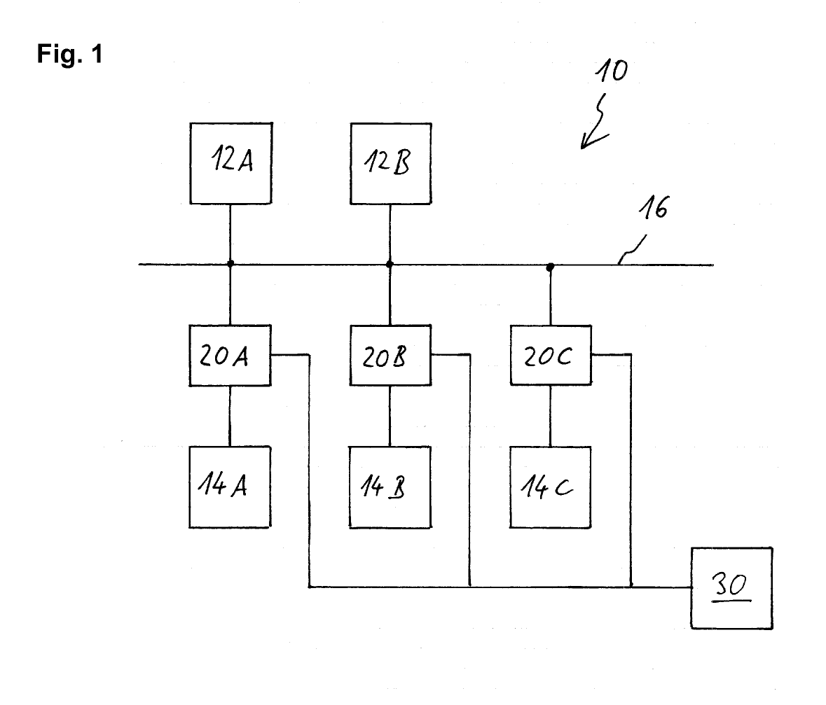

FIG. 1 schematically shows an example of a digital device 10. The digital device 10 may comprise, for example, one or more requestor units, one or more responder units, and a bus connecting each responder unit to each requestor unit. For example, the device 10 shown in the Figure comprises a first requestor unit 12A, a second requestor unit 12B, a first, second, and third responder unit 14A, 14B, and 14C, and a bus 16. Each requestor unit may, for instance, be a microprocessor or processor core, a direct-memory access (DMA) unit, or a peripheral capable to generate bus accesses. The responder units 14A, 14B, and 14C may, for instance, be a static random access memory unit (SRAM), a non-volatile memory (Flash), or peripheral units (peripherals) such as a pulse-width modulation unit (PWM), a wireless interface, a sensor unit, a serial or parallel communication interface or any other kind of digital data processing device capable of responding to the requestor units. Each of the responder units 14A, 14B, 14C may comprise a set of memory elements. Each memory element may be accessible individually by each or at least one of the requestor units, e.g., by requestor units 12A, 12B, via the bus 16.

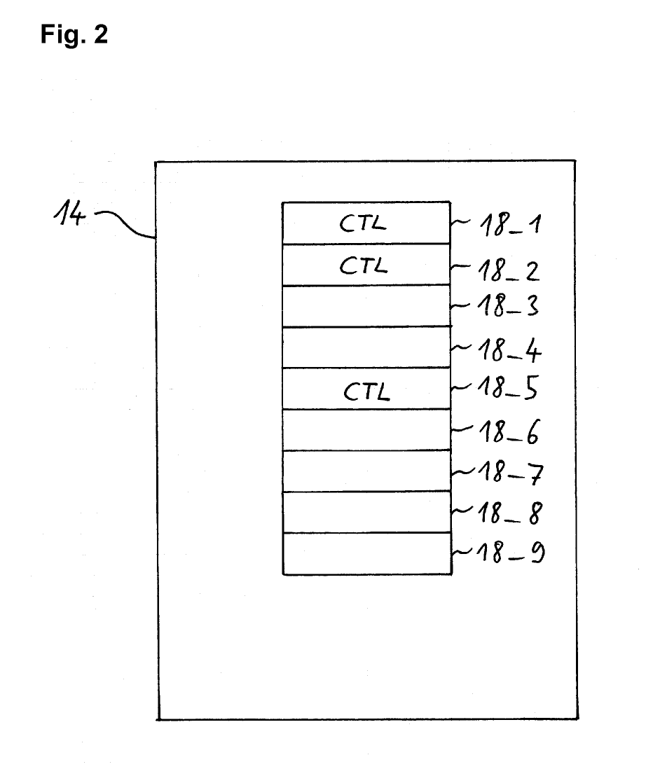

An example of a responder unit 14 is schematically shown in FIG. 2. The responder unit 14 may be representative of any one of the responder units discussed herein. For example, each of the responder units 14A, 14B, and 14C in FIG. 1 may be arranged as described in reference to FIG. 2. The responder unit 14 may notably comprise a set of memory elements 18_K, where K is an index specifying the respective memory element. In FIG. 2, a set of nine memory elements 18_1 to 18_9 is shown. The responder unit 14 may, however, comprise a far greater number of memory elements. Each memory element 18_K may, for instance, be a register. A register may be composed of a certain number of flip-flops, such as 8, 16, or 32 flip-flops, for example. The register size, i.e., the number of information bits it may store or, equivalently, the number of flip-flops it contains, may coincide with a word size of the digital device 10. Some registers, however, may contain fewer bits than other registers. The memory elements 18_K of the responder unit 14 may notably include one or more elements that are used for control purposes (control elements). In an example in which the responder unit 14 is a peripheral unit and the memory elements 18_K are registers, the control elements may also be referred to as the peripheral control registers. In the example of FIG. 2, the memory elements 18_1, 18_2, and 18_5 are control elements. In another example (not shown), any other memory element 18_K of the responder unit 14 may be a control element. A control element may be defined as a memory element that is arranged to store configuration data of the responder unit 14. The proper functioning of the responder unit 14 may therefore be affected if the data stored in one of the control elements is accidentally changed by, for example, an environmental impact. In one example, the control elements, e.g., control elements 18_1, 18_2, and 18_5, are initialized only during a set-up phase of the digital device 10, and from thereon, an application running on the digital device 10 may have to rely on the integrity of the information stored in these registers.

Referring back to the example of FIG. 1, each of the responder units 14A, 14B, 14C may thus comprise a plurality of responder elements 18_K which may be accessible by the requestor units 12A, 12B via the bus 16 and which may include one or more critical memory elements such as the memory elements 18_1, 18_2, and 18_5 in FIG. 2. Any memory element among the memory elements of a given responder unit may be defined as a critical memory element to indicate that the integrity of its data content must be ensured.

The digital device 10 may further comprise one or more wrapper units 20A, 20B, 20C. The digital device 10 may comprise fewer or more wrapper units than those shown in FIG. 1. Each of the wrapper units 20A, 20B, and 20C may connect one of the responder units 14A, 14B, and 14C to the bus 16. Each of the responder units 14A, 14B, 14C may thus be associated with one of the wrapper units 20A, 20B, and 20C and vice versa. In other words, the responder units and the wrapper units may be arranged in pairs, each pair comprising a responder unit, e.g., responder unit 14A, and a wrapper unit, e.g., wrapper unit 14B, connected between the respective responder unit, e.g., responder unit 14A, and the bus 16. There is not necessarily a wrapper unit for every responder unit. Furthermore, the digital device 10 may comprise further responder units which are not described in this application and which may differ from those described herein.

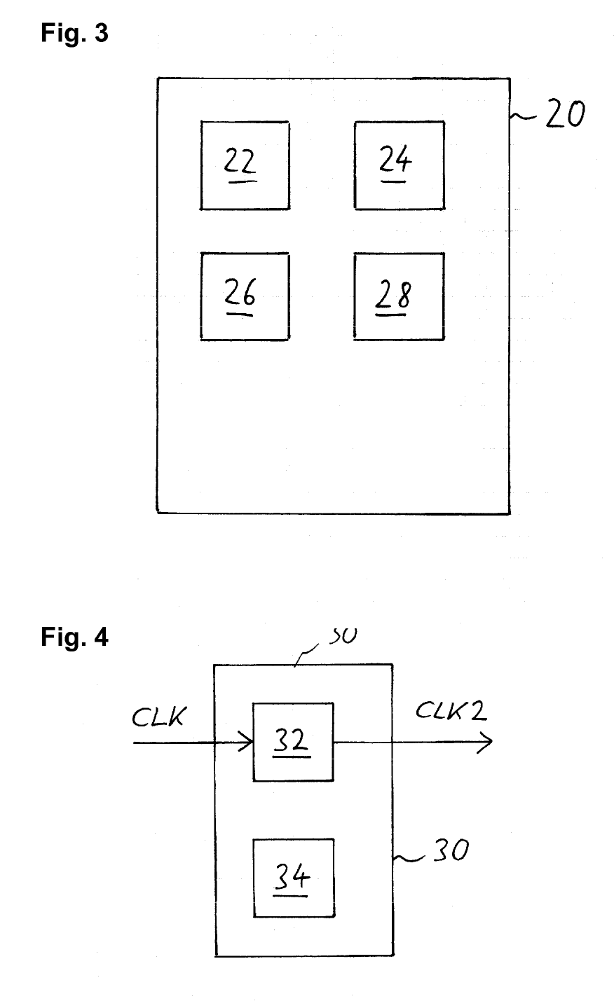

Each of the wrapper units 20A, 20B, and 20C may comprise an interface unit 22, a configuration unit 24, a checksum unit 26, and a verification unit 28, for example (see FIG. 3).

The interface unit 22 of a wrapper unit 20 may be arranged to enable the requestor units of the digital device 10, e.g., the requestor units 12A and 12B, to access the responder elements, e.g., 18_1 to 18_9, of the respective responder unit 14 that is associated with this wrapper unit. For example, the requestor units 12A and 12B may thus be enabled to access the responder elements of the responder unit 14A via the wrapper unit 20A. Each wrapper unit may thus be designed so as to pass on any communication between the one or more requestor units 12A, 12B and the respective responder unit 14.

The checksum unit 26 may be arranged to respond to any write access to any of the critical responder elements (e.g., to the critical responder elements 18_1, 18_2, and 18_5 in FIG. 2) by computing and storing a reference checksum. The reference checksum may be computed by applying a checksum algorithm to the data content of a subset of the critical memory elements, wherein the subset may comprise at least the critical responder element that is accessed by said write access.

The checksum 26 and the verification unit 28 may be merged in a single unit or comprise shared circuitry. This may be particularly convenient because both the checksum unit 26 and the verification unit 28 may use the same algorithm for computing and re-computing the reference checksum, respectively.

In one example, the mentioned subset comprises only the single critical memory element to which the write access takes place. In this case, the checksum may thus be computed by applying the checksum algorithm to only this single memory element. For example, when one of the requestor units 12A, 12B performs a write access to memory element 18_2, the checksum unit 26 may compute a checksum for the data that is written into this single memory element 18_2 and store the computed checksum as a reference checksum.

In another example, the mentioned subset comprises the entire subset of critical memory elements of the given responder unit 14. For example, referring again to FIG. 2, when one of the requestor units 12A, 12B performs a write access to the critical memory element 18_2, the checksum unit 26 may compute a checksum by applying the checksum algorithm to the data content of the entire set of critical memory elements 18_1, 18_2, and 18_5. The checksum unit 26 may further store the thus computed checksum as a reference checksum. In a related example, the checksum may be stored centrally and not in the individual checksum units 26.

The checksum associated with a given subset of critical memory elements may be recomputed at a later instant to check whether the data content of the respective subset has changed. In the above-described first example in which a checksum is provided individually for each critical memory element, such a check (integrity test) may thus be performed individually for each memory element. In the above-described second example, in which a single checksum is provided for the entire set of memory elements 18_K (K=1 . . . N), a single integrity test may be performed to check the integrity of the data content of the entire set of critical memory elements.

A checksum, is a data item, e.g., a string or a numerical value, that is computed by applying a checksum algorithm, also known as a checksum function, to an input data item, and which is shorter than the input data item and which is different for two input data items that differ slightly.

In other words, the verification unit 28 may be arranged to perform an integrity test which may comprise: computing a verification checksum by reapplying the checksum algorithm to the data content of the mentioned subset of critical responder elements, and verifying whether the verification checksum is identical to the reference checksum. The integrity test may be performed repeatedly, e.g., in certain intervals of time. The verification unit 28 may be further arranged to trigger an error action if the verification checksum is not identical to the respective reference checksum. The error action may include, for instance, signaling the error to the requestor units, e.g., 12A and 12B, or at least to one of the requestor units, or to another block (not shown) within the device 10 that is responsible collecting and reacting on erroneous conditions within the device. Alternatively or in addition, the error action may include correcting the corrupted data content. In this respect, it is noted that the checksum may be or comprise an error correcting code (ECC). The verification unit 28 may thus use the reference checksum to correct the corrupted data content of the respective subset of critical memory elements.

A major benefit of the architecture described herein may be that the wrapper units, e.g., wrapper units 20A, 20B, and 20C may be nonintrusive for the associated responder units, e.g., 14A, 14B, 14C and do not require a modification of the particular responder unit they are associated with. A wrapper unit as described herein may therefore be easily integrated in an existing architecture with existing responder units in which one or more requestor units are connected to one or more responder units via a bus. In other words, the same type of responder unit may be implemented within, e.g., a system on chip (SoC), with an associated wrapper unit as well as without. If the respective responder unit, e.g., responder unit 14A lacks an associated wrapper unit, e.g., wrapper unit 20A, it will, of course, also lack the data integrity monitoring or data correction mechanism provided by the wrapper unit. This may be acceptable if the respective responder unit does not provide any safety relevant function or does not have memory elements for holding control information.

The configuration unit 24 (cf. FIG. 3) is an optional unit that may be configurable for enabling a user to define any memory element among the memory elements of the associated responder units as a critical memory element. This is unit is optional, because it is also possible to omit it and provide a static definition of critical memory elements for a particular responder unit type; a static definition refers here to a definition that is specified at design or synthesis time of the associated hardware, which cannot be modified by software at application run time. As such a static definition allows a SoC designer or system architect to configure the wrapper units before fabrication of the corresponding device. A definition that can be modified by software may thus enable a software developer, customer, or other user to configure the wrapper unit to his specific needs, e.g., to adapt it to a specific application to be executed by the requestor units. The configuration unit 24 may also be one-time configurable. The configuration unit 24 may, for example, comprise a table specifying the selection of critical memory elements, that table being implemented in a one-time write or flash memory and applied during startup of the device. The selection of critical responder elements may thus be made permanent or configured during startup, for example, before the device 10 is released on the market.

The digital device 10 may further comprise a shared unit 30 (cf. FIG. 1) connected to each wrapper unit 20A, 20B, 20C. The shared unit 30 may be arranged to provide one or more functions that may be common to these wrapper units. Functions provided by other units described herein, such as the verification unit 28, may also be integrated in the shared unit 30. The hardware of the digital device 10 may thus be reduced. The one or more common functions may, for example, include the computation of the reference checksum as well the computation of the verification checksum. It is noted that the checksum algorithm may be the same for every wrapper unit 14A, 14B, and 14C and for every subset of critical responder elements that has its own reference checksum. The shared unit 30 may, for example, comprise a dedicated arithmetic logic unit 34 for computing the checksum.

Another common functionality that may be performed by the shared unit 30 is the storage of checksum information for all wrapper units 20 or a subset of these wrapper units. This storage may be done within a set of dedicated memory elements within the shared unit 30, a dedicated RAM element within the shared unit 30, or by using a portion of the “normal” memory within the device 10 for this purpose; in the later case the shared unit 30 will perform the required read and write accesses to record or retrieve the checksum data from memory.

The digital device 10 may be arranged to be clocked by a at least one clock signal. For example, the digital device may comprise a clock unit (not shown) for generating a first clock signal CLK. Alternatively, the digital device may be arranged to receive the first clock signal CLK from an external clock unit (not shown). The digital device 10 may further comprise a clock divider 32 (cf. FIG. 4) for generating a second clock signal CLK2 that has a lower clock rate than the first clock signal. The verification unit 28 (cf. FIG. 3) may in this case be arranged to repeat the integrity test in response to, e.g., each triggering edge of the second clock signal. A triggering edge may be defined as a rising edge or as a falling edge or as any edge of the respective clock signal. An integrity test may thus be performed for each subset within each responder unit 14A, 14B, and 14C at the frequency of the second clock signal. The integrity tests associated with the various subsets in the various wrapper units may be performed in parallel or sequentially, depending on the details of the design. A design in which the integrity tests are performed sequentially may be less expensive.

The clock divider 32 may be integrated in, for example, the shared unit 30. The shared unit 30 may further comprise a wrapper counter (not shown) arranged to select one of the wrapper units 20A, 20B, and 20C in a specified order and in accordance with, e.g., the second clock signal. The clock divider 32 may be configurable by software; which allows to specify the interval time of the checks by the verification unit. The shared unit 30 may further comprise, e.g., a subset counter (not shown) arranged to select one of the subsets within the wrapper units 20A, 20B, 20C. The shared unit 30 may thus be operated to specify an order and the interval in which the integrity tests may be performed for the subsets within the wrapper units 20A, 20B, 20C. For instance, the integrity test may be performed first for all subsets within the responder unit 14A, then for all subsets within the responder unit 14B, then for all subsets within the responder unit 14C, and then again for all subsets within the responder unit 14A, and so on. In other words, the shared unit 30 may be arranged to count through all subsets within the group of critical responder elements within the digital device 10 in accordance with the second clock signal. The second clock signal may have a lower frequency than the first clock signal, and the frequency of the integrity tests may thus be reduced, and power consumption by the involved units may be reduced accordingly. The frequency of the second clock signal should, however, be sufficiently high so that the interval between two consecutive integrity tests for any subset in any responder unit is not longer than a specific interval; e.g. the process safety time (PST) for a safety device.

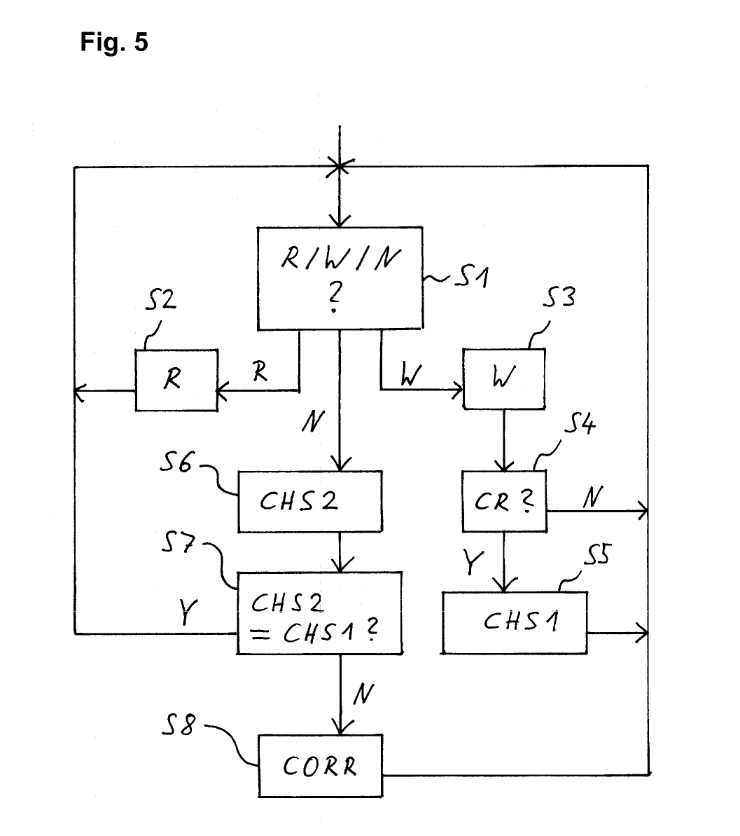

Referring now to FIG. 5, operation of an example of a wrapper unit, e.g., the wrapper unit 20A of the responder unit 14A, is described. The process flow may start in block S1 with the wrapper unit 20A determining whether there is a read access, a write access, or no access to one of the memory elements of its associated responder unit 14A. If there is a read access, the interface unit 22 may perform this read access. The interface 22 may, to this end, forward a corresponding read access signal from the bus 16 to the responder unit 14A. From block S2, the process flow may return to block S1 with, e.g., the next triggering edge of, e.g., the first clock signal CLK mentioned above.

If, however, there is a write access on the bus 16, the interface 22 may perform the write access (block S3) by, e.g., forwarding the write access signal to the responder unit 14A. The checksum unit 26 may further determine whether the write access is directed to one of the critical memory elements of the responder unit 14A. If the write access is directed to a non-critical memory element, the process flow may return to block S1 with, e.g., the next triggering edge of, e.g., the first clock signal CLK. If, however, the write access is directed to one of the critical memory elements, the checksum unit 26 may compute a new reference checksum for the subset that comprises the critical memory element that was the object of the write access, taking into account the data to be written into at least one of the critical memory elements. It may be recalled that this subset may comprise one or more memory elements depending on the architecture. Block S5, i.e., the computation of the new reference checksum may need to include also critical memory elements that are not modified by the data to be written so that the new reference checksum will account for the new data content that has been written to the critical memory element as well as the content of unmodified critical memory elements. The new reference checksum for the subset that comprises the critical memory element that was the object of the write access, is then stored somewhere, i.e. in the checksum unit 22, the wrapper unit 20, or the shared unit 30, to allow later usage of this value. From block S5, the process flow may return to block S1.

If, however (now referring back to block S1), there is no read access and no write access, the verification unit 28 may perform an integrity test comprising, e.g., blocks S6, S7, and S8. It is noted that block S1 may, for instance, be performed at the frequency of the above-mentioned first clock signal CLK, and the integrity test S6, S7, S8 may be performed at the frequency of, e.g., the second clock signal CLK2. In other words, the integrity test S6, S7, S8 may be performed less frequently than block S1. The integrity test S6, S7, S8 may thus be absent for some iterations of block S1, although this is not indicated in the Figure. In one example, the integrity test S6, S7, S8 may be performed in only one out of, e.g., 100 repetitions of block S1.

The integrity test S6, S7, S8 may comprise computing, checking and eventually correcting the subset referred to above in reference to block S5 based on the stored verification checksum CHS1. For this purpose, the verification unit 28 may use the interface unit 22 to perform a read access (in block S6) to the responder unit 14 to retrieve the actual values of the critical memory elements 18_K making up this subset. This access may be a “local” access from the wrapper unit 20 to the responder unit 14 that is not forwarded to the bus 16 and thus not visible to other units within the device. The retrieved content of the critical memory elements 18_K is then used to calculate the verification checksum CHS2 in a subsequent step within block S6.

The integrity test may further comprise comparing the calculated verification checksum CHS2 against the reference checksum CHS1 (block S7) and triggering an error action (block S8) if these two checksums differ. The error action S8 may, for example, comprise correcting the data in the respective subset, or sending a “correction request signal” to another unit (not shown) to request a correction by this unit. It is worth to note that, i.e. when the using an ECC checksum, a certain amount of errors (single bit flips) can be corrected based solely on the actual data and stored checksum; in this particular case the correct content can be calculated and written back into the associated critical memory elements 18_K. An additional functionality performed as part of the error action S8 may be setting a flag to identify the detection of erroneous data; which may be further used by the device.

From block S8, the process flow may return to block S1. If, however, the verification checksum coincides with the reference checksum, the process flow may return from block S7 to block S1.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Also for example, in one embodiment, the illustrated examples may be implemented as circuitry located on a single integrated circuit or within a same device. For example, the requestor units and the responder units may be located on a single integrated circuit. Alternatively, the examples may be implemented as any number of separate integrated circuits or separate devices interconnected with each other in a suitable manner. For example, the requestor units and the wrapper units may be located on separate integrated circuits.

Also for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A digital device comprising:
one or more requestor units;
one or more responder units;
a bus, each of said responder units being connected to said one or more requestor units via said bus, wherein each of said one or more responder units comprises a plurality of responder elements which are accessible by said requestor units via said bus and which include one or more critical responder elements; and
one or more wrapper units, wherein each of said wrapper units connects one of said responder units to said bus and comprises:
an interface unit arranged to enable said requestor units to access the responder elements of the respective responder unit associated with the respective wrapper unit; and
a checksum unit arranged to respond to any write access to any one of said critical responder elements by computing and storing a reference checksum; wherein said checksum unit is arranged to compute said reference checksum by applying a checksum algorithm to a subset of said critical responder elements, said subset comprising at least said write-accessed critical responder element.

2. The digital device of claim 1, wherein each of said wrapper units further comprises a configuration unit which is configurable to define any one of said responder elements as a critical responder element

3. The digital device of claim 2, wherein said configuration unit is hardwired at synthesis time or one-time configurable at device startup.

4. The digital device of claim 1, wherein said subset comprises only said write-accessed responder element.

5. The digital device of claim 1, wherein said subset comprises any combination of critical responder elements among said critical responder elements.

6. The digital device of claim 1, further comprising a shared unit connected to each of said one or more wrapper units and arranged to provide one or more functions which are common to said one or more wrapper units.

7. The digital device of claim 1, wherein said one or more commons functions include generating said reference checksum.

8. The digital device of claim 1, wherein each of said wrapper units further comprises a verification unit arranged to perform an integrity test, wherein the verification unit is configured to:
operate the interface unit for reading the data content of a group of critical memory elements including at least one of the critical responder elements,
compute a verification checksum by re-applying said checksum algorithm to the data content of said group of critical memory elements,
verify whether said verification checksum is identical to said reference checksum, and
trigger an error action if said verification checksum is not identical to the respective reference checksum.

9. The digital device of claim 8, wherein said reading of said data content is not visible to any other block than the involved wrapper unit and the corresponding responder unit.

10. The digital device of claim 8, arranged to be clocked by a first clock signal and comprising a clock divider for generating a second clock signal having a lower clock rate than said first clock signal, wherein said verification unit arranged to repeat said integrity test at a triggering edge of said second clock signal.

11. The digital device of claim 8, arranged to repeat said integrity test in parallel or in series
for any subset of the wrapper units and
for any subset of the critical memory elements of a wrapper units 14 within the said subset of wrapper units.

12. The digital device of claim 8, wherein said verification unit is arranged to perform said integrity test while none of said requestor units is accessing the respective responder unit.

13. The digital device of claim 1, wherein said checksum is or comprises an error detection and correction code.

14. The digital device of claim 1, wherein said digital device is a system on chip.

15. The digital device of claim 1, wherein said responder elements are registers.
